(19) United States
(12) Patent Application Publication
(10) Pub. No.: US 2026/0353561 A1
(43) Pub. Date: Nov. 5, 2026

(54) PACKAGE STRUCTURE AND METHOD FOR FORMING THE SAME

(71) Applicant: Advanced Semiconductor Engineering, Inc., Kaohsiung (TW)

(72) Inventor: Meng-Chen HSIEH, Kaohsiung (TW)

(73) Assignee: Advanced Semiconductor Engineering, Inc., Kaohsiung (TW)

(21) Appl. No.: 19/197,917

(22) Filed: May 2, 2025

(51) Int. Cl. H05K 1/14; H05K 1/181; H05K 3/341

(52) U.S. Cl. CPC H05K 1/144; H05K 1/181; H05K 3/3442; H05K 2201/042; H05K 2201/10015

(57) ABSTRACT

A package structure and a method for forming the same are provided. The package structure includes a first substrate, a second substrate, a first electronic component, a second electronic component, a first electrical connector, a second electrical connector, and a third electrical connector. The second substrate is over the first substrate. The first electronic component and the second electronic component are between the first substrate and the second substrate, and the first electronic component and the second electronic component have different thicknesses. The first electrical connector connects the first electronic component to the first substrate. The second electrical connector and the third electrical connector collectively connect the second electronic component to the first substrate.

### BACKGROUND

### 1. Technical Field

The present disclosure relates generally to a package structure and a method for forming a package structure.

### 2. Description of the Related Art

In a 3D stacking structure where passive components are used to connect upper and lower substrates, the passive components currently applied for connecting these substrates all have the same height. With the advancement of technology and increasing demands for functions of devices, it may become necessary to use passive components of various heights or sizes to connect the upper and lower substrates. Therefore, there are technical challenges that need to be overcome in connecting upper and lower substrates with passive components with different heights or sizes.

### SUMMARY

In one or more arrangements, a package structure includes a first substrate, a second substrate, a first electronic component, a second electronic component, a first electrical connector, a second electrical connector, and a third electrical connector. The second substrate is over the first substrate. The first electronic component and the second electronic component are between the first substrate and the second substrate, and the first electronic component and the second electronic component have different thicknesses. The first electrical connector connects the first electronic component to the first substrate. The second electrical connector and the third electrical connector collectively connect the second electronic component to the first substrate.

In one or more arrangements, a package structure includes a first substrate, a second substrate, a first electronic component, a second electronic component, a first electrical connector, a second electrical connector, and a third electrical connector. The first electronic component and the second electronic component are between the first substrate and the second substrate, and are spaced apart from the first substrate by different distances. The first electrical connector abuts the first substrate and the first electronic component. The second electrical connector and the third electrical connector are connected to each other, the second electrical connector abuts the first substrate, and the third electrical connector abuts the second electronic component.

In one or more arrangements, a method for forming a package structure includes providing a substrate including a first pad and a second pad exposed by a surface; applying a first solder paste on the first pad; forming a first electrical connector from the first solder paste; applying a plurality of second solder pastes on the second pad and the first electrical connector, wherein a melting point of the second solder pastes is lower than a melting point of the first solder paste; and connecting a first electronic component and a second electronic component to the second solder pastes.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of a package structure in accordance with some arrangements of the present disclosure.

FIG. 1C is a top view of a portion of a package structure in accordance with some arrangements of the present disclosure.

FIG. 2A to FIG. 2F illustrate various stages of an exemplary method for forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

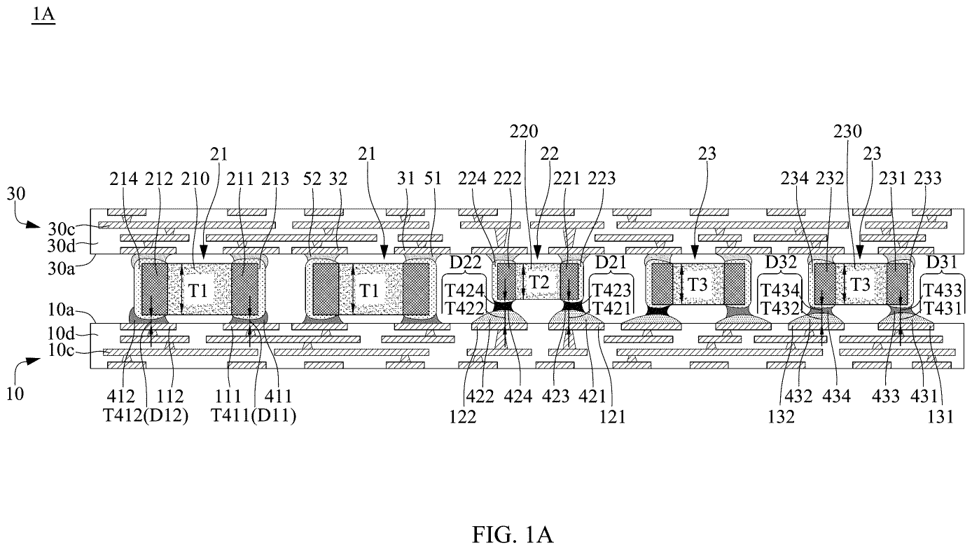

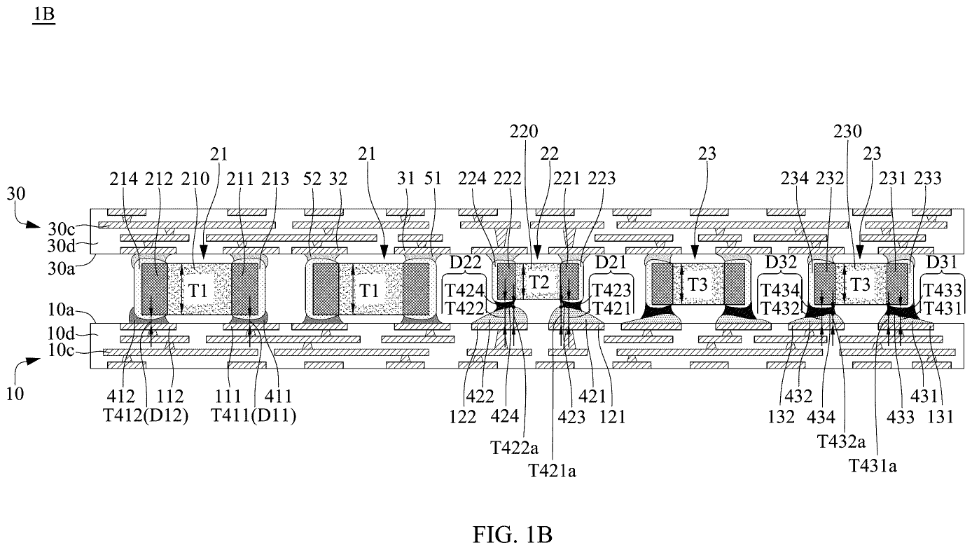

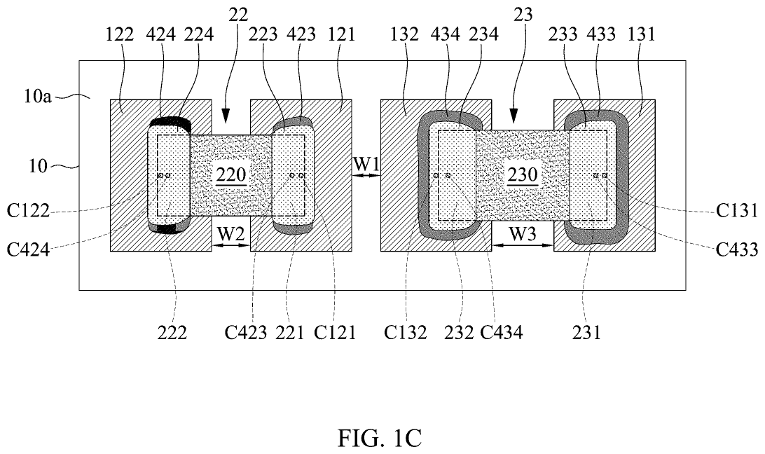

FIG. 1A is a cross-section of a package structure 1A in accordance with some arrangements of the present disclosure. The package structure 1A may include substrates 10 and 30, electronic components 21, 22, and 23, and electrical connectors 411, 412, 421, 422, 423, 424, 431, 432, 433, 434, 51, and 52.

The substrate 10 may include, for example, a printed circuit board (PCB), such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. The substrate 10 may include an integrated fan-out wafer or integrated circuit dies, which may be arranged in an array. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may be or include a build-up substrate. The substrate 10 may include a surface 10a (also referred to as a top surface or an upper surface). In some arrangements, the substrate 10 includes an interconnection structure including conductive elements 10c and a dielectric structure 10d encapsulating the conductive elements 10c. In some arrangements, the conductive elements 10c include conductive traces, conductive layers, conductive pads, and/or conductive vias. In some arrangements, the substrate 10 (or the conductive elements 10c) may include pads 111, 112, 121, 122, 131, and 132 exposed from the surface 10a. The pads 111, 112, 121, 122, 131, and 132 may be electrically conductive pads. The substrate 10 (or the conductive elements 10c) may further include pads exposed from a surface opposite to the surface 10a and serving as external interconnects to connect to external elements (e.g., solder balls). The pads (or the external interconnects) may be connected to additional input/output (I/O) bumps that electrically connect the conductive elements 10c to external components.

The substrate 30 may be disposed over the substrate 10. The substrate 30 may include, for example, a printed circuit board (PCB), such as a paper-based copper foil laminate, a composite copper foil laminate, or a polymer-impregnated glass-fiber-based copper foil laminate. The substrates 10 and 30 may be referred to as a lower PCB and an upper PCB, and the lower PCB aligns with the upper PCB. The substrate 30 may include an interconnection structure, such as a plurality of conductive traces and/or a plurality of conductive vias. The substrate 30 may include an integrated fan-out wafer or integrated circuit dies, which may be arranged in an array. In some arrangements, the substrate 30 includes a ceramic material, a metal plate, an organic substrate, or a leadframe. In some arrangements, the substrate 30 may include a two-layer substrate which includes a core layer and a conductive material and/or structure disposed on an upper surface and a bottom surface of the substrate 30. The conductive material and/or structure may include a plurality of conductive traces. The substrate 30 may be or include a build-up substrate. The substrate 30 may include a surface 30a (also referred to as a bottom surface or a lower surface). In some arrangements, the substrate 30 includes an interconnection structure including conductive elements 30c and a dielectric structure 30d encapsulating the conductive elements 30c. In some arrangements, the conductive elements 30c include conductive traces, conductive layers, conductive pads, and/or conductive vias. In some arrangements, the substrate 30 (or the conductive elements 30c) may include pads 31 and 32 exposed from the surface 30a. The pads 31 and 32 may be electrically conductive pads.

The electronic components 21, 22, and 23 may be disposed between and electrically connected to the substrate 10 and the substrate 30. In some arrangements, the electronic components 21, 22, and 23 have different thicknesses (e.g., different thicknesses T1, T2, and T3 are). In some arrangements, the electronic components 21, 22, and 23 may have different widths. In some arrangements, a footprint area occupied by the electronic component 21 is greater than a footprint area occupied by the electronic component 23, and the footprint area occupied by the electronic component 23 is greater than a footprint area occupied by the electronic component 22. In some arrangements, the electronic components 21, 22, and 23 are spaced apart from the substrate 10 by different distances (e.g., different distances D11, D12, D21, D22, D31, and D32). The distances D11, D12, D21, D22, D31, and D32 may independently range from about 20 μm to about 70 μm. A difference between any one of the distances D11 and D12 and any one of the distances D21, D22, D31, and D32 may be greater than about 30 μm, 35 μm, or 40 μm. A difference between any two of the distances D21, D22, D31, and D32 may be less than about 20 μm, 15 μm, or 10 μm.

The electronic components 21, 22, and 23 each or collectively may be referred to as an electrical transmission region between the substrate 10 and the substrate 30. The electronic components 21, 22, and 23 may be referred to as connection lines within the electrical transmission region. The connection lines may include electrical paths, which may include at least one or more data paths, one or more power routing paths, or a combination thereof. The electronic components 21, 22, and 23 may be or include passive components. In some arrangements, the electronic components 21, 22, and 23 include surface mount devices (SMDs). In some arrangements, the electronic components 21, 22, and 23 include capacitors or the like. For example, the electronic components 21, 22, and 23 may independently include a metal-oxide-metal (MOM) capacitor or a metal-insulator-metal (MIM) capacitor. In some arrangements, as shown in FIG. 1A, the electronic component 22 is disposed between the electronic components 21 and the electronic components 23. There may be various permutations of the electronic components 21, 22, and 23, for example, the electronic components 21 may be disposed between the electronic component 22 and the electronic components 23. The substrates 10 and 30 may be arranged with a respective permutation of the electronic components 21, 22, and 23 according to actual applications.

In some arrangements, the conductive elements 10c include a power management integrated circuit (PMIC). In some arrangements, the conductive elements 30c include a PMIC. The PMIC and the electronic components 21, 22, and 23 may collectively include or be referred to as a power routing region. In some arrangements, the electronic components 21, 22, and 23 directly connecting the substrate 10 and the substrate 30 may reduce a resistive path within the power routing region. In some arrangements, the substrate 10 and the substrate 30 may independently be or include a build-up substrate having finer design rules and can include one or more embedded components (e.g., embedded PMICs, embedded capacitors, or the like), such that the size of the substrate as well as the package structure can be reduced.

In some arrangements, the electronic component 21 is disposed over and electrically connected to the pads 111 and 112 of the substrate 10. In some arrangements, the electronic component 21 is spaced apart from the pad 111 and the pad 112 by a distance D11 and a distance D12, respectively. The distances D11 and D12 may be substantially the same or different from each other. In some arrangements, the electronic component 21 is electrically connected to the pads 31 and 32 of the substrate 30. In some arrangements, the electronic component 21 includes a base layer 210 and electrodes 211 and 212 (also referred to as “contacts”). The electrode 211 may be opposite to the electrode 212. The base layer 210 may be an insulating layer, e.g., a ceramic layer. In some arrangements, the electronic component 21 further includes a solder element 213 covering the electrode 211 and a solder element 214 covering the electrode 212. The electrode 211 and the solder element 213 may be referred to as a terminal (also referred to as “a first terminal”) of the electronic component 21, and the electrode 212 and the solder element 214 may be referred to as a terminal (also referred to as “a second terminal”) of the electronic component 21. In some arrangements, the terminals of the electronic component 21 are electrically connected to the pads 111 and 112, respectively. The solder elements 213 and 214 may be referred to as solder structures, solder layers, solder balls, reflowable elements, or the like.

In some arrangements, the electronic component 22 is disposed over and electrically connected to the pads 121 and 122 of the substrate 10. In some arrangements, the electronic component 22 is spaced apart from the pad 121 and the pad 122 by a distance D21 and a distance D22, respectively. At least two of the distances D11, D12, D21, and D22 may be substantially the same or different from each other. In some arrangements, the electronic component 22 is electrically connected to the pads 31 and 32 of the substrate 30. In some arrangements, the electronic component 22 includes a base layer 220 and electrodes 221 and 222 (also referred to as “contacts”). The electrode 221 may be opposite to the electrode 222. The base layer 220 may be an insulating layer, e.g., a ceramic layer. In some arrangements, the electronic component 22 further includes a solder element 223 covering the electrode 221 and a solder element 224 covering the electrode 222. The electrode 221 and the solder element 223 may be referred to as a terminal (also referred to as “a first terminal”) of the electronic component 22, and the electrode 222 and the solder element 224 may be referred to as a terminal (also referred to as “a second terminal”) of the electronic component 22. In some arrangements, the terminals of the electronic component 22 are electrically connected to the pads 121 and 122, respectively. The solder elements 223 and 224 may be referred to as solder structures, solder layers, solder balls, reflowable elements, or the like.

In some arrangements, the electronic component 23 is disposed over and electrically connected to the pads 131 and 132 of the substrate 10. In some arrangements, the electronic component 23 is spaced apart from the pad 131 and the pad 132 by a distance D31 and a distance D32, respectively. At least two of the distances D11, D12, D21, D22, D31, and D32 may be substantially the same or different from each other. In some arrangements, the electronic component 23 is electrically connected to the pads 31 and 32 of the substrate 30. In some arrangements, the electronic component 23 includes a base layer 230 and electrodes 231 and 232 (also referred to as “contacts”). The electrode 231 may be opposite to the electrode 232. The base layer 230 may be an insulating layer, e.g., a ceramic layer. In some arrangements, the electronic component 23 further includes a solder element 233 covering the electrode 231 and a solder element 234 covering the electrode 232. The electrode 231 and the solder element 233 may be referred to as a terminal (also referred to as “a first terminal”) of the electronic component 23, and the electrode 232 and the solder element 234 may be referred to as a terminal (also referred to as “a second terminal”) of the electronic component 23. In some arrangements, the terminals of the electronic component 23 are electrically connected to the pads 131 and 132, respectively. The solder elements 233 and 234 may be referred to as solder structures, solder layers, solder balls, reflowable elements, or the like.

The electrical connectors 411, 412, 421, 422, 423, 424, 431, 432, 433, and 434 may be disposed between the substrate 10 and the electronic components 21, 22, and 23. In some arrangements, the electrical connectors 411, 412, 421, 422, 423, 424, 431, 432, 433, and 434 electrically connect the electronic components 21, 22, and 23 to the substrate 10. In some arrangements, the electrical connectors 411, 412, 421, 422, 423, 424, 431, 432, 433, and 434 include solder materials. The electrical connectors 411, 412, 421, 422, 423, 424, 431, 432, 433, and 434 may independently include Sn, Ag, Cu, SnSb, or an alloy thereof. In some arrangements, the electrical connectors 411, 412, 421, 422, 423, 424, 431, 432, 433, and 434 are formed of solder pastes. The electrical connectors 411, 412, 421, 422, 423, 424, 431, 432, 433, and 434 may include or be referred to as solder elements, solder structures, solder layers, solder balls, solder bars, reflowable elements, metal adhesion layers, or the like. In some arrangements, the electrical connectors 411, 412, 421, 422, 423, 424, 431, 432, 433, and 434 and the solder elements 213, 214, 223, 224, 233, and 234 include different materials. In some arrangements, the electrical connectors 411, 412, 423, 424, 433, and 434 and the electrical connectors 421, 422, 431, and 432 include different materials. The electrical connectors including solder bars may have relatively large sizes and areas that can cover relatively large areas of the corresponding pads, the electrical connection performance can be increased, and thus the electrical performance of the package structure 1A can be enhanced.

In some arrangements, the electrical connectors 411 and 412 connect the electronic component 21 to the substrate 10. In some arrangements, the electrical connectors 411 and 412 abut the electronic component 21 and the substrate 10. In some arrangements, the electrical connector 411 electrically connects the terminal (e.g., the electrode 211 and the solder element 213) of the electronic component 21 to the pad 111, and the electrical connector 412 electrically connects the terminal (e.g., the electrode 212 and the solder element 214) of the electronic component 21 to the pad 112. In some arrangements, the electrical connector 411 contacts the solder element 213 and the pad 111, and the electrical connector 412 contacts the solder element 214 and the pad 112. In some arrangements, the electrical connector 412 may include a horizontal section stacked between the solder element 214 and the pad 112, and the electrical connector 412 may include a vertical section extending over at least a lateral side of the solder element 214.

In some arrangements, the electrical connectors 421, 422, 423, and 424 connect the electronic component 22 to the substrate 10. In some arrangements, the electrical connectors 421 and 423 collectively electrically connect the electronic component 22 to the substrate 10. In some arrangements, the electrical connectors 422 and 424 collectively electrically connect the electronic component 22 to the substrate 10. In some arrangements, the electrical connectors 421 and 423 collectively electrically connect the terminal (e.g., the electrode 221 and the solder element 223) of the electronic component 22 to the pad 121, and the electrical connectors 422 and 424 collectively electrically connect the terminal (e.g., the electrode 222 and the solder element 224) of the electronic component 22 to the pad 122. In some arrangements, the electrical connector 421 is connected to the electrical connector 423, the electrical connector 422 is connected to the electrical connector 424, the electrical connectors 421 and 422 abut the substrate 10, and the electrical connectors 423 and 424 abut the electronic component 22. In some arrangements, the electrical connector 421 contacts the pad 121, and the electrical connector 423 contacts the solder element 223 and the electrical connector 421. In some arrangements, the electrical connector 422 contacts the pad 122, and the electrical connector 424 contacts the solder element 224 and the electrical connector 422. In some arrangements, the electrical connector 423 is vertically stacked between the electrical connector 421 and the electronic component 22. In some arrangements, the electrical connector 424 is vertically stacked between the electrical connector 422 and the electronic component 22. In some arrangements, the solder element 223 connects the electrode 221 to the electrical connector 423, and the solder element 224 connects the electrode 222 to the electrical connector 424. In some arrangements, a geometric center of the pad 121 is misaligned with a geometric center of the electrical connector 423. In some arrangements, a geometric center of the pad 122 is misaligned with a geometric center of the electrical connector 424.

In some arrangements, the electrical connectors 421 and 423 collectively may be referred to as a buffer layer configured to reduce a stress between the electronic component 22 and the substrate 10 so as to compensate the difference in the distance D21 between the electronic component 22 and the substrate 10 and the distances between the electronic components 21 and 23 and the substrate 10. In some arrangements, the electrical connectors 422 and 424 collectively may be referred to as a buffer layer configured to reduce a stress between the electronic component 22 and the substrate 10 so as to compensate the difference in the distance D22 between the electronic component 22 and the substrate 10 and the distances between the electronic components 21 and 23 and the substrate 10.

In some arrangements, the electrical connectors 431, 432, 433, and 434 connect the electronic component 23 to the substrate 10. In some arrangements, the electrical connectors 431 and 433 collectively electrically connect the electronic component 23 to the substrate 10. In some arrangements, the electrical connectors 432 and 434 collectively electrically connect the electronic component 23 to the substrate 10. In some arrangements, the electrical connectors 431 and 433 collectively electrically connect the terminal (e.g., the electrode 231 and the solder element 233) of the electronic component 23 to the pad 131, and the electrical connectors 432 and 434 collectively electrically connect the terminal (e.g., the electrode 232 and the solder element 234) of the electronic component 23 to the pad 132. In some arrangements, the electrical connector 431 is connected to the electrical connector 433, the electrical connector 432 is connected to the electrical connector 434, the electrical connectors 431 and 432 abut the substrate 10, and the electrical connectors 433 and 434 abut the electronic component 23. In some arrangements, the electrical connector 431 contacts the pad 131, and the electrical connector 433 contacts the solder element 233 and the electrical connector 431. In some arrangements, the electrical connector 432 contacts the pad 132, and the electrical connector 434 contacts the solder element 234 and the electrical connector 432. In some arrangements, the electrical connector 433 is vertically stacked between the electrical connector 431 and the electronic component 23. In some arrangements, the electrical connector 434 is vertically stacked between the electrical connector 432 and the electronic component 23. In some arrangements, the solder element 233 connects the electrode 231 to the electrical connector 433, and the solder element 234 connects the electrode 232 to the electrical connector 434. In some arrangements, a geometric center of the pad 131 is misaligned with a geometric center of the electrical connector 433. In some arrangements, a geometric center of the pad 132 is misaligned with a geometric center of the electrical connector 434.

In some arrangements, the electrical connectors 431 and 433 collectively may be referred to as a buffer layer configured to reduce a stress between the electronic component 23 and the substrate 10 so as to compensate the difference in the distance D31 between the electronic component 23 and the substrate 10 and the distances between the electronic components 21 and 22 and the substrate 10. In some arrangements, the electrical connectors 432 and 434 collectively may be referred to as a buffer layer configured to reduce a stress between the electronic component 23 and the substrate 10 so as to compensate the difference in the distance D32 between the electronic component 23 and the substrate 10 and the distances between the electronic components 21 and 22 and the substrate 10. In some arrangements, the distance D31 may be different from the distance D32 due to warpage occurred to the substrate 30, such that the distance D31 may be greater than or less than the distance D32. The electrical connectors 433 and 434 formed of solder pastes may serve as buffer layers configured to reduce a stress between the electronic component 23 and the substrate 10 so as to compensate the difference in the distances D31 and D32 when bonding the electronic component 23 to the substrate 10.

In some arrangements, a thickness T411 of the electrical connector 411 is substantially the same as a thickness T423 of the electrical connector 423 and a thickness T433 of the electrical connector 433. In some arrangements, a thickness T412 of the electrical connector 412 is substantially the same as a thickness T424 of the electrical connector 424 and a thickness T434 of the electrical connector 434. In some arrangements, the electrical connectors 411, 412, 423, 424, 433, and 434 have substantially the same thickness. In some arrangements, the thickness T434 of the electrical connector 434 may be different from a thickness T433 of the electrical connector 433 due to the warpage of the substrate 30.

In some arrangements, a thickness T421 of the electrical connector 421 is different from the thickness T423 of the electrical connector 423. In some arrangements, the thickness T421 of the electrical connector 421 is greater than the thickness T423 of the electrical connector 423. In some arrangements, the thickness T421 of the electrical connector 421 is different from a thickness T431 of the electrical connector 431. In some arrangements, the thickness T421 of the electrical connector 421 is greater than the thickness T431 of the electrical connector 431. In some arrangements, a thickness T422 of the electrical connector 422 is different from the thickness T424 of the electrical connector 424. In some arrangements, the thickness T422 of the electrical connector 422 is greater than the thickness T424 of the electrical connector 424. In some arrangements, the thickness T422 of the electrical connector 422 is different from a thickness T432 of the electrical connector 432. In some arrangements, the thickness T422 of the electrical connector 422 is greater than the thickness T432 of the electrical connector 432.

In some arrangements, the thickness T421 is a maximum width extending between a topmost point and a bottom surface (e.g., the surface 10a) of the electrical connector 421. The distance D21 may be a sum of the thickness T421 and the thickness T423. In some arrangements, the thickness T422 is a maximum width extending between a topmost point and a bottom surface (e.g., the surface 10a) of the electrical connector 422. The distance D22 may be a sum of the thickness T422 and the thickness T424. In some arrangements, the thickness T423 is a maximum width extending between a topmost point and a bottom surface (e.g., the surface 10a) of the electrical connector 423. The distance D31 may be a sum of the thickness T431 and the thickness T433. In some arrangements, the thickness T424 is a maximum width extending between a topmost point and a bottom surface (e.g., the surface 10a) of the electrical connector 424. The distance D32 may be a sum of the thickness T432 and the thickness T434.

In some arrangements, a width of the electrical connector 411 and/or a width of the electrical connector 412 may be greater than a width of the electrical connectors 423, 424, 433, and/or 434.

The electrical connectors 51 and 52 may be disposed between the substrate 30 and the electronic components 21, 22, and 23. In some arrangements, the electrical connectors 51 and 52 electrically connect the electronic components 21, 22, and 23 to the substrate 30. The electrical connectors 51 and 52 may be referred to as solder elements, solder structures, solder layers, solder balls, reflowable elements, micro bumps, pillar bumps, or the like. The electrical connectors 51 and 52 may independently include a solder material, e.g., Sn, Ag, Cu, SnSb, or an alloy thereof. In some arrangements, the electrical connectors 51 and 52 and the solder elements 213, 214, 223, 224, 233, and 234 include different materials. In some arrangements, the electrical connectors 51 and 52 and the electrical connectors 411, 412, 423, 424, 433, and 434 include different materials. The electrical connectors including micro bumps or pillar bumps may have relatively small sizes or widths that can provide small pitches for electrical connections, and thus the size of the package structure 1A can be reduced.

According to some arrangements of the present disclosure, the electrical connectors 421, 421, 431, and 433 are configured to provide elevated heights (e.g., greater than about 30 μm, 35 μm, or 40 μm) to the electrical connections between the electronic components 22 and 23 and the substrate 10, and the electrical connectors 411, 412, 423, 424, 433, and 434 are configured to electrically connect the electronic components 21, 22, and 23 to the substrate 10. Therefore, because the electrical connectors 421, 421, 431, and 433 provide elevated heights related to the heights of the electrical connectors 411 and 412, despite that the electronic components 22 and 23 have smaller thicknesses than the electronic components 21 and thus generate the relatively large distances between the electronic components 22 and 23 and the substrate 10, the electronic components 22 and 23 can bond to the substrate 10. Accordingly, the reliability of the package structure 1A is improved, and the process for forming the package structure 1A including electronic components having different thicknesses is more flexible.

In addition, according to some arrangements of the present disclosure, the electrical connectors 423, 424, 433, and 434 are formed of solder pastes instead of solder balls and formed by printing patterned solder pastes on the cured or solid electrical connectors 421, 422, 431, and 432 instead of placing solder balls on the electrical connectors 421, 422, 431, and 432. Therefore, solder masks or solder resists for defining spaces for accommodating solder balls can be omitted. In addition, the thickness of a solder paste can be relatively small compared to that of a solder ball and can be adjusted by the printing operation, and thus the flexibility of adjusting the thicknesses of the electrical connectors formed of solder solders is improved significantly.

FIG. 1B is a cross-section of a package structure 1B in accordance with some arrangements of the present disclosure. The package structure 1B is similar to the package structure 1A in FIG. 1A, and the differences therebetween are described as follows.

In some arrangements, the electrical connector 421 may have a maximum thickness T421a extending between a topmost point and a bottom surface (e.g., the surface 10a) of the electrical connector 421, and the topmost point is exposed by the electrical connector 423. In some arrangements, the electrical connector 422 may have a maximum thickness T422a extending between a topmost point and a bottom surface (e.g., the surface 10a) of the electrical connector 422, and the topmost point is exposed by the electrical connector 424. In some arrangements, the topmost points of the electrical connectors 421 and 422 are closer to a gap between the electrical connectors 421 and 422 than to a gap between adjacent electronic components.

In some arrangements, the electrical connector 431 may have a maximum thickness T431a extending between a topmost point and a bottom surface (e.g., the surface 10a) of the electrical connector 431, and the topmost point is at an edge of the electrical connector 433. In some arrangements, the electrical connector 432 may have a maximum thickness T432a extending between a topmost point and a bottom surface (e.g., the surface 10a) of the electrical connector 432, and the topmost point is at an edge of the electrical connector 434. In some arrangements, the topmost points of the electrical connectors 431 and 432 are closer to a gap between the electrical connectors 431 and 432 than to a gap between adjacent electronic components.

FIG. 1C is a top view of a portion of a package structure in accordance with some arrangements of the present disclosure. In some arrangements, FIG. 1C illustrates a top view of the electronic components 22 and 23, the pads 121, 122, 131, and 132, and electrical connectors 423, 424, 433, and 434 shown in FIG. 1A or FIG. 1B.

In some arrangements, a geometric center C121 of the pad 121 is misaligned with a geometric center C423 of the electrical connector 423 from a top view perspective. In some arrangements, a geometric center C122 of the pad 122 is misaligned with a geometric center C424 of the electrical connector 424 from a top view perspective. In some arrangements, a geometric center C131 of the pad 131 is misaligned with a geometric center C433 of the electrical connector 433 from a top view perspective. In some arrangements, a geometric center C132 of the pad 132 is misaligned with a geometric center C434 of the electrical connector 434 from a top view perspective.

In some arrangements, the electrical connectors 423, 424, 433, and 434 have irregular shapes from a top view perspective. The electrical connectors 423, 424, 433, and 434 may each have an oval shape or an octagon shape from a top view perspective. The electrical connectors 423, 424, 433, and 434 may each have a hollow cylindrical shape. In some arrangements, the electrical connectors 423, 424, 433, and 434 may protrude beyond at least two sides of the corresponding solder elements 223, 224, 233, and 234 from a top view perspective.

In some arrangements, a distance W1 between the pad 121 and the pad 132 is less than a distance W2 between the pads 121 and 122 under the electronic component 22 and a distance W3 between the pads 131 and 132 under the electronic component 23. In some arrangements, the geometric centers of the electrical connectors are closer to a gap (e.g., a gap with the distance W2 and a gap with the distance W3) between the electrical connectors than to a gap (e.g., a gap with the distance W1) between adjacent electronic components, such that the solder pastes for forming the electrical connectors can be prevented from overflowing toward pads of adjacent electronic components.

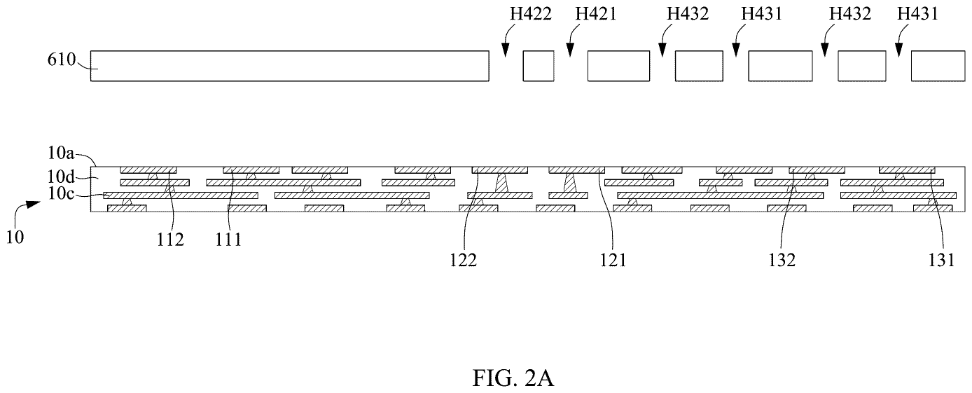

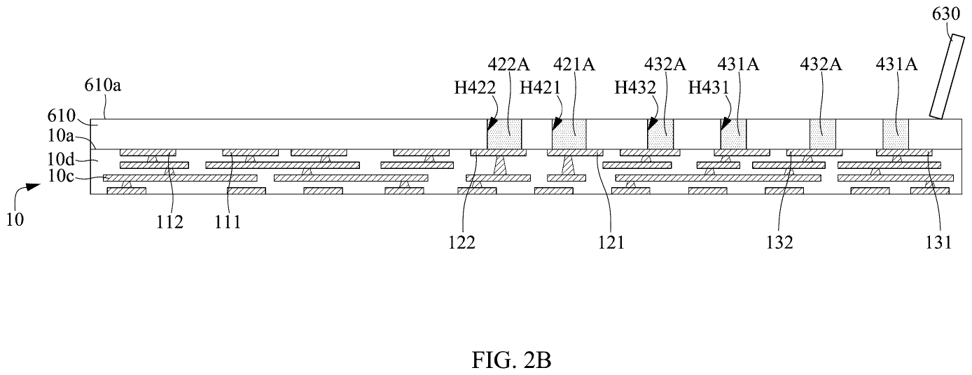

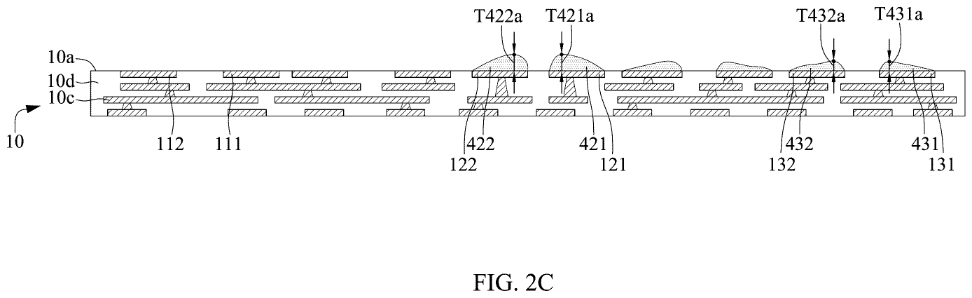

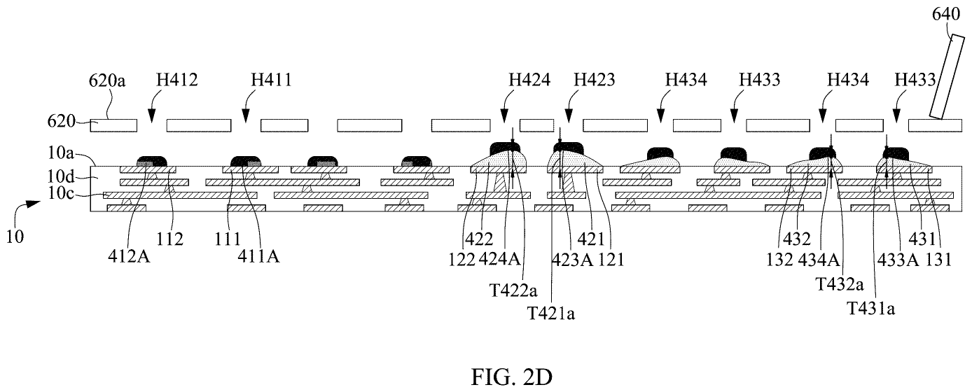

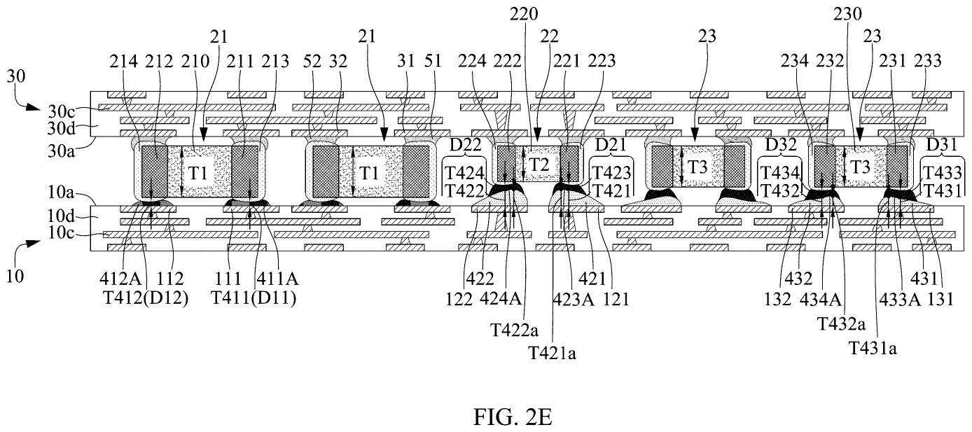

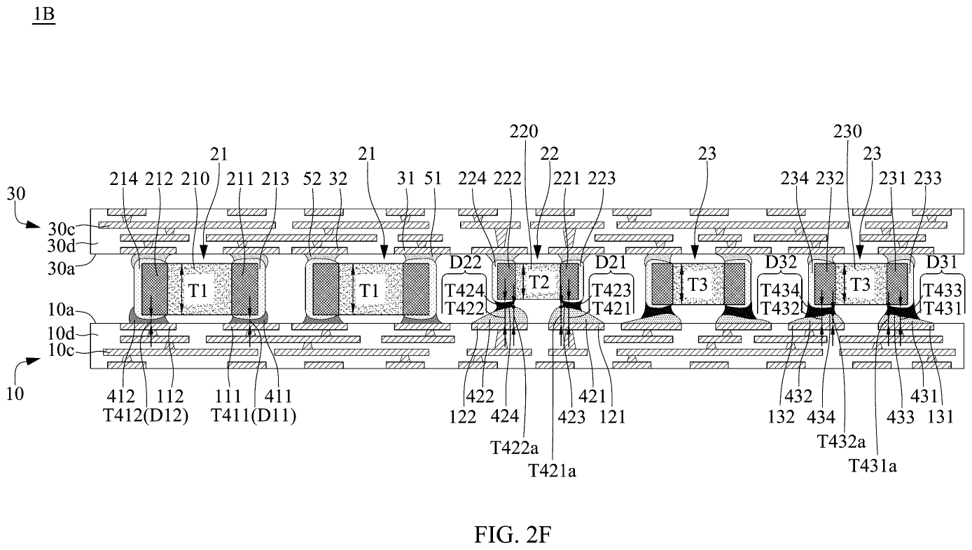

FIG. 2A to FIG. 2F illustrate various stages of an exemplary method for forming a package structure 1B in accordance with some arrangements of the present disclosure.

Referring to FIG. 2A, a substrate 10 including pads 111, 112, 121, 122, 131, and 132 exposed by a surface 10a may be provided. A mask 610 having through holes that expose some of the pads of the substrate 10 may be provided. In some arrangements, the mask 610 includes through holes H421, H422, H431, and H432 exposing the pads 121, 122, 131, and 132 without exposing the pads 111 and 112. In some arrangements, the through holes H421, H422, H431, and H432 have substantially the same depth. In some arrangements, the through holes H421 and H422 and the through holes H431 and H432 have different widths. In some arrangements, the through holes H421 and H422 are wider than the through holes H431 and H432. In some arrangements, the widths of the H421, H422, H431, and H432 are less than widths of the corresponding pads 121, 122, 131, and 132.

Referring to FIG. 2B, solder pastes 421A and 422A may be applied on the pads 121 and 122, and solder pastes 431A and 432A may be applied on the pads 131 and 132. In some arrangements, the solder pastes 421A and 422A are applied on the pads 121 and 122 through the through holes H421 and H422 of the mask 610. In some arrangements, the solder pastes 431A and 432A are applied on the pads 131 and 132 through the through holes H431 and H432 of the mask 610. A solder paste material may be applied on a surface 610a of the mask 610, and a blade 630 may traverse across the mask 610 to move the solder paste material and fill at least some of the solder paste material in the through holes. In some arrangements, the blade 630 is angled to the surface 610a to push the solder paste material to fill into the through holes. In some arrangements, the volumes of the solder pastes 421A, 422A, 431A and 432A are defined by the corresponding through holes in which the solder pastes are filled. In some arrangements, the through holes H421, H422, H431, and H432 (or the solder pastes 421A, 422A, 431A and 432A) are misaligned with the corresponding pads 121, 122, 131, and 132. In some arrangements, the widths of the H421, H422, H431, and H432 are less than widths of the corresponding pads 121, 122, 131, and 132 so as to provide alignment tolerance that allows the solder pastes 421A, 422A, 431A and 432A to be formed within ranges of the pads 121, 122, 131, and 132 without overflowing toward adjacent pads.

Referring to FIG. 2C, the solder pastes 421A, 422A, 431A and 432A may be cured to form electrical connectors 421, 422, 431 and 432. In some arrangements, the solder pastes 421A, 422A, 431A and 432A may be cured by performing a reflow operation. In some arrangements, a cleaning operation may be performed to remove residues (e.g., residues from the flux in the solder pastes). The cleaning operation may be a water cleaning operation by providing water and distributing water over the electrical connectors 421, 422, 431 and 432. In some arrangements, the thicknesses (e.g., thicknesses T421a and T422a) of the electrical connectors 421 and 422 may be different from the thicknesses (e.g., thicknesses T431a and T432a) of the electrical connectors 431 and 432 due to the difference in volumes of the solder pastes 421A and 422A and the volumes of the solder pastes 431A and 432A. In some arrangements, the volumes of the solder pastes 421A and 422A are greater than the volumes of the solder pastes 431A and 432A, and the solder pastes 421A, 422A, 431A and 432A may extend over and substantially cover the surfaces of the corresponding pads 121, 122, 131, and 132, such that small volumes of the solder pastes may result in formation of the electrical connectors with smaller thicknesses. In some arrangements, the thicknesses of the electrical connectors 421 and 422 may be greater than the thicknesses of the electrical connectors 431 and 432. Therefore, despite that the solder pastes 421A, 422A, 431A and 432A are applied through the same mask 610 in a single operation, the thicknesses of the as-formed electrical connectors 421, 422, 431 and 432 may be controlled and adjusted to predetermined values by adjusting the widths or sizes of the through holes H421, H422, H431 and H432 of the mask 610.

Referring to FIG. 2D, solder pastes 411A and 412A may be applied on the pads 111 and 112, and solder pastes 423A, 424A, 433A, and 434A may be applied on the electrical connectors 421, 422, 431, and 432. In some arrangements, a melting point of the solder pastes 411A, 412A, 423A, 424A, 433A, and 434A is lower than a melting point of the solder pastes 421A, 422A, 431A, and 432A. In some arrangements, the melting point of the solder pastes 411A, 412A, 423A, 424A, 433A, and 434A is lower than the melting point of the solder pastes 421A, 422A, 431A, and 432A by at least about 30 °C, for example, 30 °C, 35 °C, 40 °C, 50 °C or greater.

In some arrangements, still referring to FIG. 2D, a mask 620 having through holes may be provided over the substrate 10. In some arrangements, the mask 620 includes through holes H411 and H412 exposing the pads 111 and 112 and through holes H423, H424, H433, and H434 exposing the electrical connectors 421, 422, 431, and 432. In some arrangements, the through holes H411, H412, H423, H424, H433, and H434 have substantially the same depth. In some arrangements, at least two of the through holes H411, H412, H423, H424, H433, and H434 have different widths. In some arrangements, the through holes H423 and H424 are wider than the through holes H433 and H434. In some arrangements, the depth of the through holes H421, H422, H431, and H432 of the mask 610 is greater than the depth of the through holes H411, H412, H423, H424, H433, and H434 of the mask 620.

In some arrangements, still referring to FIG. 2D, the solder pastes 411A and 412A may be applied on the pads 111 and 112, and the solder pastes 423A, 424A, 433A, and 434A may be applied on the electrical connectors 421, 422, 431, and 432. In some arrangements, the solder pastes 411A and 412A are applied on the pads 111 and 112 through the through holes H411 and H412 of the mask 620. In some arrangements, the solder pastes 423A, 424A, 433A, and 434A are applied on the electrical connectors 421, 422, 431, and 432 through the through holes H423, H424, H433, and H434 of the mask 620. A solder paste material may be applied on a surface 620a of the mask 620, and a blade 640 may traverse across the mask 620 to move the solder paste material and fill at least some of the solder paste material in the through holes and on the pads and the electrical connectors underneath. In some arrangements, the blade 640 is angled to the surface 620a to push the solder paste material to fill into the through holes. In some arrangements, the volumes of the solder pastes 411A, 412A, 423A, 424A, 433A, and 434A are defined by the corresponding through holes in which the solder pastes are filled. In some arrangements, the through holes H411, H412, H423, H424, H433, and H434 (or the solder pastes 411A, 412A, 423A, 424A, 433A, and 434A) are misaligned with the corresponding pads 111 and 112 and the corresponding electrical connectors 421, 422, 431, and 432. In some arrangements, the widths of the H411 and H412 are less than widths of the corresponding pads 111 and 112, and the widths of the H423, H424, H433, and H434 are less than widths of the corresponding electrical connectors 421, 422, 431, and 432, so as to provide alignment tolerance that allows the solder pastes 411A, 412A, 423A, 424A, 433A, and 434A to be formed within ranges of the pads 111 and 112 and the electrical connectors 421, 422, 431, and 432 without overflowing toward adjacent pads or electrical connectors.

Referring to FIG. 2E, the electronic components 21, 22, and 23 may be connected to the solder pastes 411A, 412A, 423A, 424A, 433A, and 434A. In some arrangements, a substrate 30 is provided, and the electronic components 21, 22, and 23 are connected to the substrate 30 through electrical connectors 51, and 52. The electronic components 21, 22, and 23 may be bonded to the substrate 30 through a laser welding process. In some arrangements, the electronic components 22 and 23 are connected to the solder pastes 411A, 412A, 423A, 424A, 433A, and 434A on the electrical connectors 421, 422, 431, and 432. In some arrangements, the solder pastes 411A, 412A, 423A, 424A, 433A, and 434A may be pushed and deformed by the pressure from the electronic components 21, 22, and 23. The solder pastes 411A, 412A, 423A, 424A, 433A, and 434A may serve as flexible portions that may deform and partially recess based on the extent to which the electronic components come into contact with and protruding into the solder pastes 411A, 412A, 423A, 424A, 433A, and 434A. With the above design, even slight differences in the distances (e.g., less than about 20 μm, 15 μm, or 10 μm.) between the electronic components 21, 22, and 23 and the substrate 10 can be compensated by the solder pastes 411A, 412A, 423A, 424A, 433A, and 434A that deform when contacting the electronic components 21, 22, and 23.

Referring to FIG. 2F, after the electronic components 21, 22, and 23 are connected to the solder pastes 411A, 412A, 423A, 424A, 433A, and 434A, the solder pastes 411A, 412A, 423A, 424A, 433A, and 434A may be cured to form electrical connectors 411, 412, 423, 424, 433, and 434. In some arrangements, the solder pastes 411A, 412A, 423A, 424A, 433A, and 434A may be cured by performing a reflow operation. In some arrangements, a cleaning operation may be performed to remove residues (e.g., residues from the flux in the solder pastes). The cleaning operation may be a water cleaning operation by providing water and distributing water over the electrical connectors 411, 412, 423, 424, 433, and 434. In some arrangements, the solder pastes 423A, 424A, 433A, and 434A are cured at a first temperature, and the solder pastes 411A, 412A, 423A, 424A, 433A, and 434A are cured at a second temperature lower than the first temperature. In some arrangements, a difference between the first temperature and the second temperature is equal to or greater than about 30 °C, for example, 30 °C, 35 °C, 40 °C, 50 °C or higher. With the above design of the difference in the curing temperatures, the electrical connectors 423, 424, 433, and 434 can remain cured and solid when curing the solder pastes 411A, 412A, 423A, 424A, 433A, and 434A, such that the elevated heights provided by the electrical connectors 423, 424, 433, and 434 can remain stable. As such, the package structure 1B illustrated in FIG. 1B may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first substrate;
a second substrate over the first substrate;
a first electronic component and a second electronic component between the first substrate and the second substrate and having different thicknesses;
a first electrical connector connecting the first electronic component to the first substrate; and
a second electrical connector and a third electrical connector collectively connecting the second electronic component to the first substrate.

2. The package structure as claimed in claim 1, wherein the third electrical connector is vertically stacked between the second electrical connector and the second electronic component.

3. The package structure as claimed in claim 2, wherein a thickness of the first electrical connector is substantially the same as a thickness of the third electrical connector.

4. The package structure as claimed in claim 2, wherein a thickness of the second electrical connector is greater than a thickness of the third electrical connector.

5. The package structure as claimed in claim 2, wherein the third electrical connector contacts the second electrical connector and the second electronic component, and the second electrical connector contacts a pad of the first substrate.

6. The package structure as claimed in claim 1, wherein the first electrical connector contacts a pad of the first substrate and the first electronic component.

7. The package structure as claimed in claim 1, wherein the first substrate comprises a pad contacting the third electrical connector, and a geometric center of the pad is misaligned with a geometric center of the third electrical connector.

8. The package structure as claimed in claim 1, further comprising:
a third electronic component between the first substrate and the second substrate and having a thickness different from a thickness of the first electronic component and a thickness of the second electronic component; and
a fourth electrical connector and a fifth electrical connector collectively connecting the third electronic component to the first substrate.

9. The package structure as claimed in claim 8, wherein the fifth electrical connector is vertically stacked between the fourth electrical connector and the third electronic component.

10. A package structure, comprising:
a first substrate and a second substrate;
a first electronic component and a second electronic component between the first substrate and the second substrate and spaced apart from the first substrate by different distances;
a first electrical connector abutting the first substrate and the first electronic component; and
a second electrical connector and a third electrical connector connected to each other and abutting the first substrate and the second electronic component, respectively.

11. The package structure as claimed in claim 10, wherein the second electronic component comprises an electrode and a solder element connecting the electrode to the third electrical connector.

12. The package structure as claimed in claim 11, wherein the third electrical connector contacts the second electrical connector and the solder element.

13. The package structure as claimed in claim 10, further comprising:
a third electronic component between the first substrate and the second substrate and spaced apart from the first substrate by a distance different from a distance between the first substrate and the first electronic component and a distance between the first substrate and the second electronic component; and
a fourth electrical connector and a fifth electrical connector connected to each other and abutting the first substrate and the third electronic component, respectively.

14. The package structure as claimed in claim 13, wherein the third electronic component comprises an electrode and a solder element connecting the electrode to the fifth electrical connector.

15. The package structure as claimed in claim 14, wherein the fifth electrical connector directly contacts the fourth electrical connector and the solder element.

16. The package structure as claimed in claim 10, wherein a width of the second electrical connector is greater than a width of the third electrical connector.

17. A method for forming a package structure, comprising:
providing a substrate comprises a first pad and a second pad exposed by a surface;
applying a first solder paste on the first pad;
forming a first electrical connector from the first solder paste;
applying a plurality of second solder pastes on the second pad and the first electrical connector, wherein a melting point of the second solder pastes is lower than a melting point of the first solder paste; and
connecting a first electronic component and a second electronic component to the second solder pastes.

18. The method as claimed in claim 17, further comprising:
providing a first mask having a first through hole exposing the first pad without exposing the second pad; and
applying the first solder paste on the first pad through the first through hole of the first mask.

19. The method as claimed in claim 17, further comprising curing the second solder pastes after connecting the first electronic component and the second electronic component to the second solder pastes.

20. The method as claimed in claim 19, wherein the first solder paste is cured at a first temperature, and the second solder pastes are cured at a second temperature lower than the first temperature.
